(19) United States
(12) Patent Application Publication
(10) Pub. No.: US 2004/0032828 A1
(43) Pub. Date: Feb. 19, 2004

(54) Service management in cellular networks

(75) Inventors: Aharon Satt, Haifa (IL); Liron Langer, Haifa (IL); Haim Zelikovsky, Hod Hasharon (IL); Yoaz Daniel, Haifa (IL)

Correspondence Address: POLSINELLI SHALTON & WELTE, P.C., 700 W. 47TH STREET, SUITE 1000, KANSAS CITY, MO, 64112-1802, US

(73) Assignee: CellGlide Technologies Corp.

(21) Appl. No.: 10/222,487

(22) Filed: Aug. 16, 2002

(51) Int. Cl. G01R 31/08

(52) U.S. Cl. 370/230; 370/235; 370/232

(57) ABSTRACT

There are disclosed methods (processes) and systems, for: 1. establishing and defining service classes and service plans; 2. monitoring and controlling parameters related to level of service for each service class; and 3. estimating the additional resources necessary to support excessive traffic demand. These methods and systems provide visibility into the network, enabling management of the network.

### TECHNICAL FIELD

The present invention is related to service management for controlling packet traffic in data networks, for example, cellular networks. In particular, the present invention is related to dynamic management of levels of service in such data networks.

### BACKGROUND

Cellular data networks, including wired and wireless networks, are currently widely and extensively used. Such networks include cellular mobile data networks, fixed wireless data networks, satellite networks, and networks formed from multiple connected wireless local area networks (wireless LANs). In each case, the cellular data networks include at least one shared media or cell.

FIG. 1 shows an exemplary Internet Protocol (IP) data network 20, formed of a host Internet Protocol (IP) network 22, that can include a server or servers, a transport network 24, (e.g., cellular mobile data network) such as servers, switches, gateways, etc., and a shared media 26 or cell. The shared media 26 communicates with end user devices 28 over links 30. These end user devices 28 can be for example, personal computers (PCs), workstations or the like, laptop or palmtop computers, cellular telephones, personal digital assistants (PDAs) or other manned and unmanned devices able to receive and/or transmit IP data. The links 30 can be wired or wireless, and for example, can be a line or channel, such as a telephone line, a radio interface, or combinations thereof. These links 30 can also include buffers or other similar hardware and/or software, so as to be logical links. Data transfers through this network 20, as packets pass through the shared media 26, over the links 30 to the respective end user devices 28.

Presently, data traffic in cellular data networks is in sufficiently managed, and the network lacks of mechanisms to enforce rich service policies and control. For example, a request arriving at the host network 22 is typically responded to, regardless of network conditions or other administrative policies. In this example, data is being transmitted to the end user devices 28, even if network resources are insufficient for successfully passing the unit of data requested to the requisite end user device 28. Data might also be transmitted to end user devices 28, even if the devices themselves cannot support receiving of that data momentarily, during temporary traffic load and lack of sufficient cell capacity, or during poor radio reception conditions.

Moreover, proper dimensioning of the data network is impossible, as specific cells in the network 20 can overflow, such that these overflows can not be controlled. This results in inconsistent levels of service to end user devices 28, as the levels of service fluctuates from those that are acceptable, to the complete lack of service.

Contemporary solutions to this problem involve modifications to routers and switches typically existing in the transport (core cellular) network 24. One such modification involves introducing prioritizing mechanisms within the switches and/or routers. These mechanisms enable partial distinctions between services, allowing for some services to be performed, but not nearly all or the maximum amount of services to be performed.

These solutions lack the ability to differentiate the level of service of the end user, as their priority mechanisms are unaware of the nature of the service involved. Moreover, these solutions are unable to either monitor or query network dimensioning data, whereby network dimensioning and/or quality of service (QoS) are not monitored. As a result, the agent or agents operating the system are unaware of the level of service being provided to the end user devices.

### SUMMARY

The present invention improves on the contemporary art by allowing for the complete distinction of service, allowing for awareness of the exact levels of service by operating agent(s) and the like. There are disclosed apparatus, methods (processes) that allow for controlling and monitoring quality of service for classes of services in cellular networks, that are performed dynamically and “on the fly.” The monitoring performed includes monitoring and analyzing both levels of service for the above service classes, and both monitoring and analyzing of network dimensioning data, both of which are done dynamically and on the fly.

The invention provides methods (processes), such as those for: 1. establishing and defining service classes and service plans; 2. monitoring and controlling parameters related to level of service for each service class; and 3. estimating the additional resources necessary to support excessive traffic demand. These methods provide visibility or vision into the network, enabling management of the network in numerous ways, including, application of traffic shaping models and mechanisms at various interfaces of the network, reconfiguring network routers and switches, adding physical resources to the network, adding or subtracting dedicated resources to data traffic (for example, in General Packet Radio Service (GPRS) systems).

There is disclosed a method (process) for monitoring and controlling data traffic in cellular networks. The method includes, establishing at least one service class, continuously monitoring Quality of Service (QoS) parameters for the at least one service class, and continuously controlling the QoS parameters for the at least one service class based on service level parameters.

There is also disclosed a server for monitoring and controlling data traffic in cellular networks. The server includes a processor programmed to: establish at least one service class; continuously monitor Quality of Service (QoS) parameters for the at least one service class; and continuously control the QoS parameters for the at least one service class based on service level parameters. The processor is typically also programmed to establish service plans.

Also disclosed is a programmable storage device (for example, a computer disk or the like), readable by a machine, tangibly embodying a program of instructions executable by a machine to perform method steps for controlling traffic in a data network, the method steps selectively executed during the time when the program of instructions is executed on the machine. These method steps include: establishing at least one service class; continuously monitoring Quality of Service (QoS) parameters for the at least one service class; and continuously controlling the QoS parameters for the at least one service class based on service level parameters.

There is disclosed a method (process) for network dimensioning. This method includes, establishing at least one service class, continuously monitoring Quality of Service (QoS) parameters for the at least one service class, and estimating resources required to accommodate excess demand. The method can additionally include establishing service plans.

Also disclosed is a server for network dimensioning. The server includes a processor programmed to: establish at least one service class; continuously monitor Quality of Service (QoS) parameters for the at least one service class; and estimate resources required to accommodate excess demand.

Also disclosed is a programmable storage device readable by a machine, tangibly embodying a program of instructions executable by a machine to perform method steps for controlling traffic in a data network, the method steps selectively executed during the time when the program of instructions is executed on the machine. These method steps include: establishing at least one service class; continuously monitoring Quality of Service (QoS) parameters for the at least one service class; and estimating resources required to accommodate excess demand.

### BRIEF DESCRIPTION OF THE DRAWINGS

Attention is now directed to the attached drawings, wherein like reference numerals or characters indicate corresponding or like components. In the drawings:

FIG. 1 is a diagram of an exemplary contemporary network;

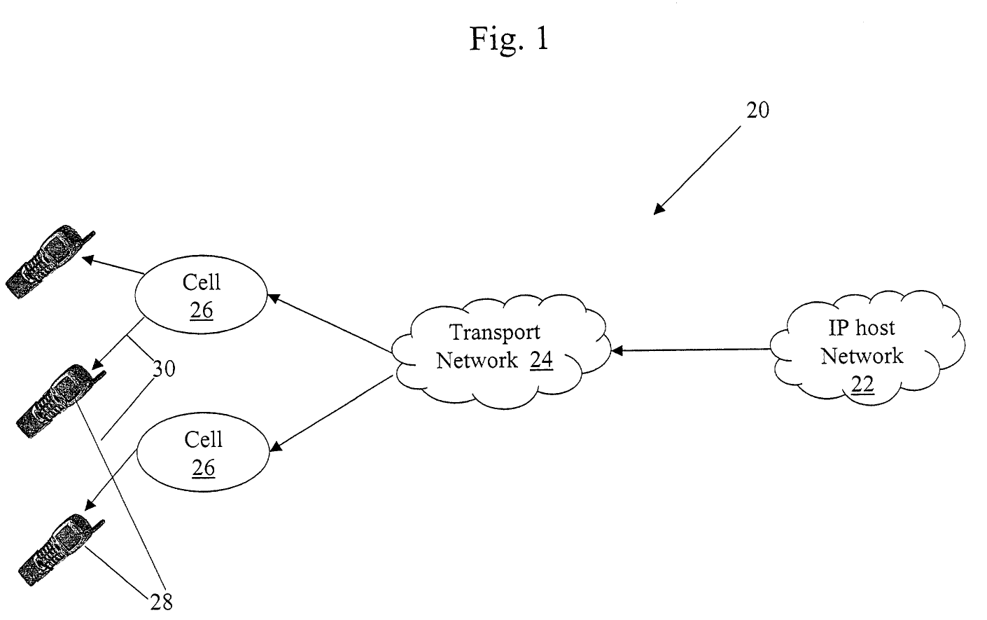

FIG. 2 is a diagram showing an exemplary network in use with an embodiment of the present invention;

FIG. 3 is a flow diagram detailing a process in accordance with an embodiment of the present invention; and

FIG. 4 is a flow diagram detailing another process in accordance with an embodiment of the present invention.

### DETAILED DESCRIPTION OF THE DRAWINGS

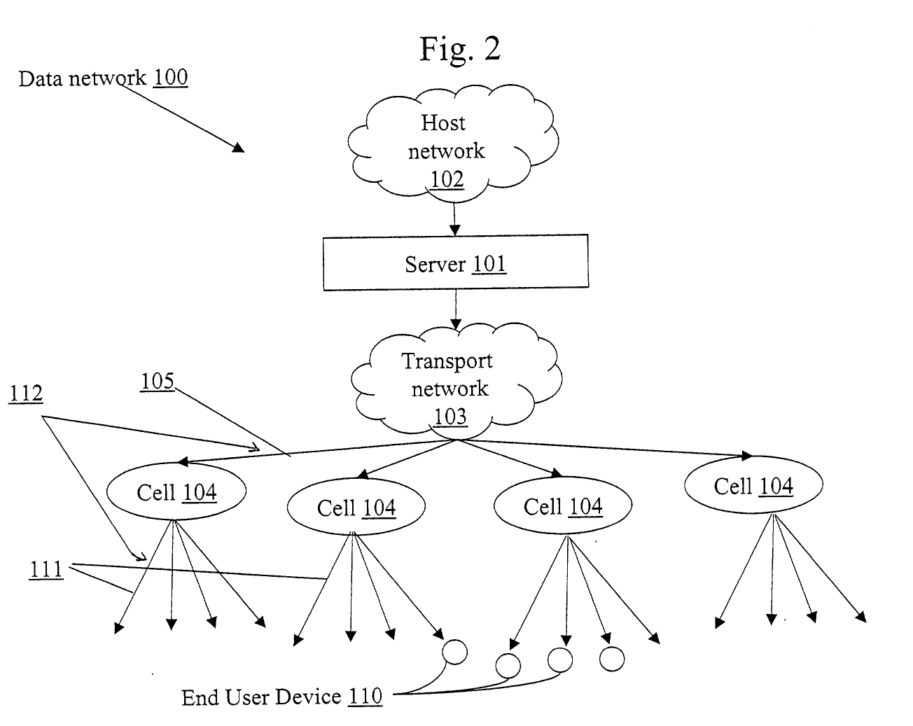

FIG. 2 shows an exemplary system 100 for performing the invention. The system 100 includes a server 101, manager gateway or the like that performs the invention, typically in software, hardware or combinations thereof. The processes performed by the server 101 are typically dynamic (continuous) and “on the fly.”

The server 101 typically includes components (hardware, software or combinations thereof) such as storage media, processors (including microprocessors), network interface media, queuing systems or devices (also referred to below as queues), and other hardware or software components. With respect to the queuing systems, they can be within the server 101 or remote from the server 101, provided that the server 101 controls these queuing systems. These queuing systems enable the server 101 to control the data traffic, enforce resource allocation including allocation of bandwidth and/or delay, and support implementation of service policies and service plans as explained in the sequel. The server 101 is in communication with a host network 102, such as the Internet, Local Area Network (LAN) or any other IP network including at least one server, and wireless network (that includes cells), or the like.

The server 101 is also in communication with a transport network 103. This transport network 103 can be for example, a cellular network. Alternately, the server 101 can reside within the transport network 103. The server 101 communicates with shared access media or cells 104, via the transport network 103 over first channels 105 (wired or wireless), lines, pipes, etc.

The server 101 measures the cell available resources, or capacity, typically in terms of bandwidth or bit-rate, or the end user device available resources, or capacity, or both. This measurement is typically done by monitoring (passive), or alternately querying (active), the respective cell, or monitoring or querying the transport network 103, or monitoring the control signaling associated with the respective cell that passed over the first channels 105, to obtain the temporary raw available capacity (bandwidth, bit-rate, resources) at the cell, for the requisite cell, or the temporary raw available capacity (bandwidth) for the end user device. The temporary raw available bandwidth may be given by the flow control signaling between the cell 104, or a server (controller) associated with the cell, and the transport network 103. The raw cell or end user device bandwidth measurements can be used as actual cell or user capacity, or available bandwidth, respectively, without modification. Alternately, the server 101 can be programmed to calculate (estimate) the cell capacity, or end user device capacity, or both, by modifying the measurements, for example, by averaging them over time or use a median filter, over a sliding time window. The end user device capacity estimations can be used for calculating an estimation for the cell capacity, for example by summing up the capacity measurements, or estimations, of the individual end user devices, across the respective cell.

End user devices 110 (cell phones, PDA's, computers, etc. and manned or unmanned) (typically of the subscribers) are provided services from one or more shared access media or cells 104, typically over second channels 111 (wired or wireless), that for example may be air interfaces, such as radio channels. The first 105 and second 111 channels, together, form links 112 (the pathway over which a transmission(s) travel from the transport network 103 to the end user device 110, and vice versa), and will be referred to in this manner throughout this document.

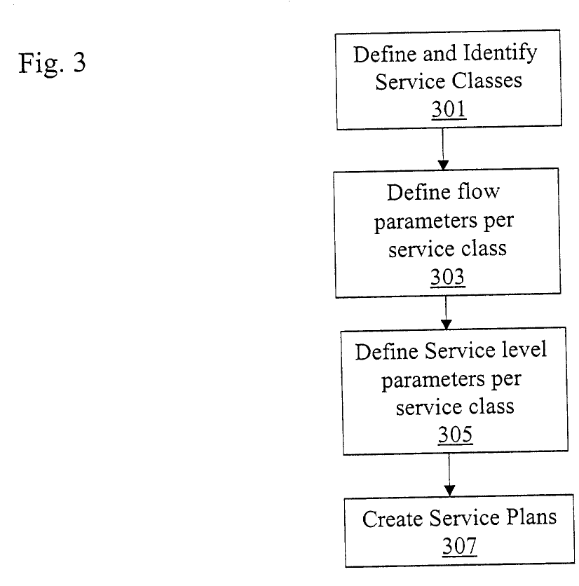

Turning to FIG. 3, a method of establishing service classes and service plans is exemplified through a flow chart. These processes may be performed by hardware, software or combinations thereof. The processes are performed dynamically and “on the fly”. Additionally, the processes performed by the server 102, detailed below, in full or in part, can also be embodied in programmable storage devices (for example, compact disks (CDs) or other magnetic or optical disks) readable by a machine or the like, or other computer-usable storage medium, including magnetic, optical or semiconductor storage, or other source of electronic signals.

This process (method) begins with an initializing process, block 301. Specifically, there is a prompt for defining and identifying service classes, or a default configuration is used if a definition is not given. In order to explain the concept of service classes, a flow is defined first. Data packet flow, or flow, is a sequence of one or more packets with common attributes, typically identified by the packet headers, for example, as having common source and common destination Internet Protocol (IP) addresses and common source and common destination ports of either Transmission Control Protocol (TCP) or User Datagram Protocol (UDP). Typically, a flow can start upon initiating a TCP connection or receiving the first packet, and end, or terminate, by teardown of the TCP connection or following certain time-out from the last received packet.

A service class is a category of flows used to maintain levels of service for a certain group or type of flows. Specific flows require specific resource treatment to yield specific levels of service. Flows differ from each other in the manner in which they utilize resources available to them, as well as in the amount of resources they require for achieving a specific level of service. Service classes are utilized as categories of flows, all of which require the same type of resource treatment and allocation. The concept of service classes enables a system administrator to configure desired levels of service, in accordance with his per-service policies, either at the network level, the sub-network level, the cell level, or combinations thereof.

Returning to block 301 of FIG. 3, service classes are defined, or identified, or initialized, or determined. For this purpose, service types are first defined. A service type is a category of services, all of which require the same qualitative treatment. The administrator may define service types himself, or except the systems defaults, which can include, for example, the following four service types:

The streaming service type. This type includes all services associated with a typical packet flow, which would require a nearly constant bit-rate throughout its duration. This type includes services such as streaming video services, voice streaming for mail services, streaming audio services, etc.

The downloading service type. This type includes all services, a typical packet flow of which would require an average bit-rate of some magnitude, for example, approximately 5 Kbps, as calculated over the flow duration. This type can include services such as file transfer services, electronic mail services, etc.

The interactive service type. This service type includes services, typically characterized by short data bursts serving interactive requests and answers, referred to as messages, requiring low latency responses.

This type may include services such as chat services, mobile transaction services, etc.

The best effort service type. This includes services the administrator does not assign any specialized treatment to.

Service types may be extended to accommodate changing behavior of flows over time, and the corresponding changing requirements for resource allocation. For instance, the downloading service type may support interactive-oriented periods within each flow, similar to the interactive service type, as detailed below. An example for such service is Web browsing or Wireless Access Protocol (WAP) service, which typically consists of interactive menu-driven messages, requiring low latency, followed by larger object downloads, requiring certain average bit-rates.

With service types defined, the process continues to define priority levels, and consequently to determine service classes. As said above, service class is a category of all flows that receive similar resource allocations, and is defined to be the category of flows sharing the same service type and priority levels.

There are two types of priority levels: absolute priority levels and relative priority levels. Both types of priority levels are defined to enable the administrator to differentiate between different service classes in terms of different resource allocation priorities.

Absolute priority levels are defined to enable the administrator to set service classes, which receive their determined level of service prior to other service classes. By definition, each absolute priority level receives access to resources before all lower absolute priority levels. Relative priority levels are defined to enable the administrator to set service classes, which potentially receive a larger relative portion of the available cell resources, if required according to the determined level of service, than other service classes of the same absolute priority.

As a result, a higher priority level service class, either absolute or relative, typically has a higher quality of service, if the cell capacity, or available resources, is insufficient to accommodate all concurrent services. The system administrator may define as many or as few priority levels as desired.

By default, the number of service classes is determined by the number of service types multiplied by the number of absolute priority levels and by the number of relative priority levels. However, the system administrator may override this by defining different numbers of absolute and relative priority levels for different service types. In this case, the number of service classes is the sum of all the combinations of absolute and relative priority levels, as defined across all service types.

Alternatively the system administrator may accept the system defaults, which, for example, might be defined by one absolute level and three relative levels. The relative levels may be, for example: 1. “gold”, the highest level; 2. “silver”, the intermediate level; and 3. “bronze”, the lowest level. Accordingly, for example, the exemplary defaults create twelve exemplary service classes: streaming gold, streaming silver, streaming bronze, download gold, download silver, download bronze, WAP gold, WAP silver, WAP bronze, web browsing gold, web browsing silver and web browsing bronze. Note that, at this point, only abstract relative priority levels have been defined, for example gold, silver and bronze. Actual numerical values, suitable for enforcement, will be defined at block 305 as described below.

The process then continues (still at block 301) by prompting or by using defaults in the absence of input, to initialize per-flow parameters, or parameters associated with the specific flows (also known as flow parameters), typically defined differently for each service class. These flow parameters are applied to all flows within each of the service classes defined. A prompt is also made for establishing service level parameters for each of the service classes. These service level parameters typically determine the minimum level of service for each of the flows of the requisite service classes, although maximum level of service, average level of service, and other service levels may be defined.

The process proceeds to block 303 where for each of the service classes identified in block 301, the server 101 prompts the system administrator, or any other authorized agent to define per-flow parameters, or flow parameters, for the requisite service class. These flow parameters typically include the following:

1. Minimum Bit Rate—Defines the minimal amount of bandwidth required to satisfy successful transmission of each flow of this service class. The default value for this parameter is 0;

2. Maximum Bit Rate—Defines the maximal amount of bandwidth each flow of the requisite service class can use at any given instant. The default value for this parameter is 100 kilo bits per second.

3. Average Bit Rate—Defines the average of bandwidth resources which should be allocated over time to each flow of the requisite service class. The default value for this parameter is 50 kilo bits per second.

4. Buffer Size—Defines the size of the buffer that the server 101 (FIG. 2) reserves for each of the requisite service class flows;

5. Burst size—Defines the maximal size of a burst of data packets to be passed with minimal delay to the end user devices, for each flow of the requisite service class. The default value for this parameter is 0; and

6. Burst Delay—Defines the maximal delay to be applied to each burst of data packets for each flow of the requisite service class. The default value for this parameter is 0.

All of the above parameters having being received, either through a prompt where a value was entered, or a non-response to the prompt, where a default was entered, the process proceeds to block 305.

Here (in block 305), the server 101 makes a prompt for defining service level parameters for each of the service classes defined in block 301 above. These service level parameters typically include:

1. Absolute Priority—Defines the precedence of each service class. This absolute priority is typically a number in the range of 0 to 7, related to as priority level. The default value for this is 0.

2. Relative Priority—Defines the relative levels of service for service classes having equal priority levels. This is normally comprised of:

a. Blocking Target—Defines the percentage of requests pertaining to the requisite service class that can be denied service out of the totality of services. This denial of service is typically made to reserve resources to other service classes. The default value for this parameter is 0.

b. Dropping Target—Defines the percentage of existing flows within the network which could be terminated while going in order to allow service to flows of other service classes. The default value for this parameter is 0.

The Blocking and Dropping targets above are example for relative priorities, or “soft priorities”, as opposed to absolute priorities, or “hard priorities”. Other parameters, typically related to the cellular user experience or the service quality, can be used instead or in addition to the blocking and dropping targets. Referring to the example given for block 301 above, where the abstract names for the relative priorities were gold, silver and bronze, here, actual numerical values are given to the relative priorities. For example, the blocking targets can be 1%, 5% and 25% for gold, silver and bronze, respectively, for downloading service type; and, the dropping targets can be 0%, 2% and 5%, for gold, silver and bronze, respectively, for downloading service type. Similarly, relative priorities (here, blocking and dropping targets) are set for all the service classes defined in block 301.

The process continues with block 307, where service plans are created. For example, a service plan can be created by mapping applications to service classes. A mapping of applications to a service class is referred to as a “service plan.” Mapping includes defining the applications, and where all flows associated with the applications would be categorized into specific service classes.

This is typically done by providing values to a set of attributes or conditions. These attributes or conditions are then made into rules, with one rule, for example, defining a service plan. Each flow arriving at the server 101 is examined according to the rules. Based on the examinations, the flow(s) are categorized into the requisite service classes.

This categorization is typically achieved by initially prompting for definition of a new service plan. This could be done by manually or electronically selecting a previous or already existing service plan, the last entered service plan, which is the default, or a modification of a previous or existing service plan.

Within the prompt, attributes to be selected in order to define a service plan, are provided. For each attribute, a single value, multiple values, or a range of values can be entered. For any attribute for which a value is not entered, the default value is “all”. These attributes typically include:

1. Application type, as can be included in packet headers;

2. Delivery protocol, as can be included in packet headers;

3. End user device type, as can be read for example, from cellular network data bases;

4. End user device identification, as can be read, for example, from switches in the cellular network;

5. Host network or sub-network identification, such as Access Point Name (APN);

6. Host identification, such as an Internet Protocol (IP) address;

7. Geographical location of end user device, as can be identified by recognizing the end user device requisite serving cell within the cellular network;

8. Date of use for the application in real time;

9. Time of day for use of the application in real time.

Once attributes have been selected, logical operators, “and”/“or”/“not” for example, can be applied to one or more selected attributes. This results in a formation of a rule or rules, that defines a service plan. Additionally, these now formed rules can be compiled into tables, lists etc.

Each flow arriving at the server 101 is analyzed, for example, against a list or table of rules. The default being a list in a “last in first out” (LIFO) order, so that the rule last defined is examined first, for example.

The now established service classes and service plans can be stored in the server 101, or any other suitable storage media.

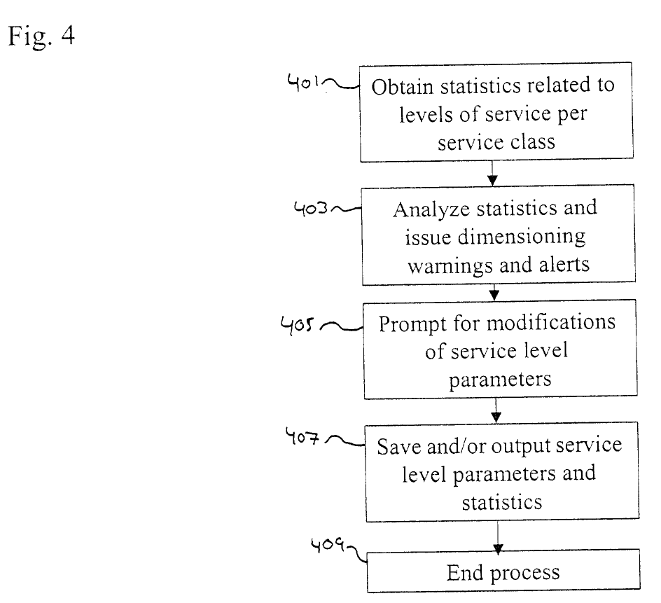

Turning to FIG. 4, a process of dynamically controlling and monitoring service levels for each of the service classes (created as detailed above) is shown in the form of a flow diagram. This process begins in block 401 with querying the shaping or queuing device, where this device is typically located, either within the server 101 or peripheral to it, for service level parameters. These parameters typically include statistics related to relative priorities, for example actual measured blocking and dropping rates, as explained below.

The queuing (or shaping) device is equipped with resource management capabilities. The resource management function operates, for example as follows, in order to control the QoS parameters, of each of the service classes based on service level parameters, including absolute and relative priorities: if there are no resources in the cell for adding one or more new flows requiring service (that is, resources for transmission through the transport network 24, over the cell or shared media 26, to the end user device 30), then these one or more flows are blocked. Lack of resources to accommodate a new flow means lack of sufficient resources in the network to provide at least the resources defined by the flow parameters (per-flow parameters) for the corresponding service class. The ratio of the number of blocked flows, in each service class, to the whole number of flows requiring service (blocked and/or granted service), as measured over certain time interval, for example 100 seconds, is defined to be the “total blocking rate” for the corresponding service class.

Additionally, if there are not enough resources in the network to keep already accommodated flows (flows that were not blocked and granted access to the network resources), one or more flows are dropped (terminated before they reached their normal end as required by the respective service). Lack of resources for keeping accommodated flow means lack of sufficient resources in the network to provide at least the resources defined by the flow parameters of the corresponding service class. The ratio of the number of dropped flows, in each service class, to the number of accommodated (granted service, and terminated either naturally or by dropping as above), as measured over certain time interval, for example 100 seconds, is defined to be the “total dropping rate” for the corresponding service class.

The resource management within the queuing or shaping device performs the following prioritization:

(1) First, the blocking or the dropping are done for all the service classes bearing the highest absolute priority, based on the momentary cell (and network) resources, as explained in part (2) below. Then, the second highest absolute priority service classes, are handled, based on the resources left from the highest priority handling: blocking and dropping are done for all the second-highest priority service classes, based on the momentary left resources. Similarly, all service classes with lower absolute priorities are handled, always based on leftover or holdover resources from previous handling.

(2) Second, within each level of absolute priority, blocking and dropping in each corresponding service class is done based on available resources in the cell (and network), and according to the relative priorities (such as total blocking and total dropping rates). For example, the policy of the resource management can be to block or drop flows such that the distance between the blocking and dropping targets, to the total blocking and total dropping rates, respectively, is as equal as possible across all service classes within the corresponding absolute priority.

Having the total blocking and total dropping rates managed according to the above service management, the result of dynamically controlling and monitoring QoS level for each of the service classes may results in measurements such as the actual (dynamically measured) total blocking and total dropping rates. There is then a prompt for modifications to the relative priorities that support levels of service. The service level parameters are further analyzed to issue alerts or warnings as to insufficient network dimensioning per service class, as detailed below. The modifications received by the server are subsequently converted to outputs. These outputs can be used in applications that shape traffic, such as in traffic shapers, for example, in accordance with commonly owned U.S. patent application Ser. No. 09/916,190, incorporated by reference herein. Alternately, these outputs can be used for reconfiguring switches and/or routers within the network 100, physical re-dimensioning of the network 100, etc.

In block 401, the server 101 obtains, by query (active) or monitoring (passive), statistics related to service levels for each service class as defined above, in block 301 of FIG. 3. These service level statistics, referred to as QoS parameters typically include:

1. Blocking Rate—The percentage of flows the server 101 (FIG. 2) did not admit for transmission to end user device 110 or devices, in order to reserve resources for other flows;

2. Dropping Rate—The percentage of flows whose transmission to the end user device 110 or devices had been stopped by the server 101 while going, to enable transmission of other flows;

3. Rejection Rate—The percentage of flows the server 101 (FIG. 2) did not admit for transmission to end user device or devices, because of insufficient cell resources; and

4. Termination Rate—The percentage of flows whose transmission to the end user device or devices had been stopped by the server 101 while going, due to a decrease in available cell bandwidth resources. Note that the blocking rate and the rejection rate form together the total blocking rate as above, whereas the dropping date and the termination rate together form the total dropping rate above.

These statistics are compiled over a pre configured time interval, the default for this time interval is, for example, 100 seconds.

With the service level statistics having been compiled, the process proceeds to block 403. The service level statistics are further analyzed to issue alerts or warnings as to insufficient network dimensioning per service class. Here, insufficient network dimensioning is typically indicated by an increase in either rejection rate or termination rate, as defined in block 401.

By default, alerts or warnings are made per service class, and are initiated whenever either rejection rate or termination rate are larger than pre configured values, the default for which being, for example, 3 percent.

A prompt is then issued, at block 405, for modifications to service class parameters, typically including relative priority parameters as defined in block 305 of FIG. 3. These prompts can be made at regular intervals, and for example, are made at 24 hour intervals.

The service level statistics compiled in block 401 are presented, typically with the prompt. This is done to enable the operator, system administrator or the like, to compare achieved service levels with goals for service levels. The prompt typically enables modifications to relative priority parameters, typically including a blocking target and a dropping target per service class, as defined in block 305 of FIG. 3 (detailed above).

The process proceeds to block 407, where the server 101 (FIG. 2) saves the current service level parameters and statistics. All of these parameters and statistics can be additionally converted to outputs. The statistics outputted include, in addition to statistics mentioned above, network dimensioning estimations. The estimation of network dimensioning typically results in an estimation of resources required to satisfy the demand for flows of all related service classes, or in the ratio of demand to available resources. An estimation of the ratio of demand to available resources is the default.

An estimation of the ratio of demand to available resources can be done for the whole network or a desired portion of it. This ratio can be used as estimation for additional cell resources (per individual cell or on the average across the cells contained in any desired portion of the network), required to accommodate the excess demand. For example, the estimation could be done per cell, which is the default.

The estimation of the resources, or cell resources, or additional cell resources, necessary to accommodate the excess demand, typically involves the following steps:

1. Calculating the demand, which is an amount of the necessary amount of resources, such as the capacity or available bandwidth, to accommodate the whole traffic demand. Accommodating the whole traffic demand typically refers to the situation that over a period of time, for example, one hour, the measured QoS parameters across the whole service classes in the cell under examination, satisfy the QoS targets. For example, the total blocking and total dropping rates, across all the service classes, do not exceed the respective blocking and dropping targets over a period of time, for example one hour. Satisfying the blocking and/or dropping QoS targets, means that the per-flow parameters of the different service classes under consideration are satisfied as well. Alternatively, this calculation may be done for only a partial set of the service classes in order to calculate and manage the demand and/or the QoS for the partial set only.

2. Comparing the available cell resources with the demand. This is typically performed over a period of time, for example one hour. For example, if the demand exceeds the available cell resources by 40%, than the cell resources should be increased by 40% to accommodate the whole traffic demand, which means that the excess relative demand is 40%. The result, which is the amount of additional cell resources required to accommodate the demand or the excess relative demand, can be further averaged over longer time periods, for example one month, possibly over the peak (or busy) hours only. The averaged amount of additional cell resources or relative excess demand, can be used as a measure for tuning the network dimensioning, to accommodate data services subject to required QoS parameters.

3. However, due to the burst-oriented nature of data traffic and the lack of “additive behavior” that enables adding demands of different data services or applications, or demands associated with service classes, to calculate the overall demand, one has to use suitable methods to estimate the demand associated with mixes of different services or applications, or with multiple service classes. The examples below present a few possible methods, based on the measured service level parameters such as blocked and dropped flows in the different service classes. In this example, the ratio of demand to cell resources are estimated by the ratio of normalized demand to normalized cell resources, calculated as detailed below.

4. When multiple cells are considered, the ratio may be averaged across the multiple cells.

The estimation could be done, for example, by the following formula:

R=D/C (1)

where,

R is the ratio to be calculated, which is estimation for the relative excess demand;

D is the normalized demand; and

C is the normalized amount of cell resources.

The normalized demand, D in Formula (1) above, is typically compiled over a pre-defined time interval, the default interval being 1 hour. The demand is typically compiled as a function of factors, including: 1. the number of flows arriving at the server 101 of FIG. 2; 2. the average of bytes arriving at the server 101 (FIG. 2) for each flow; 3. the average duration of each flow transmission; 4. the average bit-rate per flow, as defined in block 303 (FIG. 3); 5. average burst size of each flow, as defined in block 303 (FIG. 3); and 6. minimum bit-rate allocated for each flow, as defined in block 303 (FIG. 3).

This compilation of demand can be done according to the following exemplary formula:

$$D = {\sum }_{i = 1}^{n} {F}_{i} {• A}_{i} / {\sum }_{i = 1}^{n} {A}_{i} \qquad ( 2 )$$

where,

Fᵢ is the number of flows arriving at server 101 (FIG. 2) for service class i;

Aᵢ is the average bit-rate per flow of service class i, as defined in block 303 (FIG. 3) above; and

N is the number of service classes, as defined in block 301 (FIG. 3).

Additionally, the normalized amount of cell resources, C in Formula (1) above, can be compiled as a function of various factors, including: 1. the number of flows admitted for transmission at the server 101 of FIG. 2; 2. the average of bytes transmitted by server 101 to end user devices 110 (FIG. 2) for each flow; 3. the average duration of each flow transmission; 4. the average bit-rate per flow, as defined in block 303 (FIG. 3); 5. average burst size of each flow, as defined in block 303 (FIG. 3); 6. average available cell bandwidth capacity as measured, for example, at cells 104 (FIG. 2) and 7. minimum bit-rate allocated for each flow, as defined in block 303 (FIG. 3). For example, the function for compiling the amount of resources “C”, could be evaluated in accordance with the following formula:

$$C = {\sum }_{i = 1}^{n} {T}_{i} {• A}_{i} / {\sum }_{i = 1}^{n} {A}_{i} \qquad ( 3 )$$

where,

Tᵢ is the number of flows admitted for transmission to end user devices 110, and the remaining variables are in accordance with those in formula (2) above.

Another method for estimating the relative excess demand is given by the following formula:

$$R = {\sum }_{i = 1}^{n} {F}_{i} {• K}_{i} {• B}_{i} / ( {G}_{i} - {H}_{i} ) / {\sum }_{i = 1}^{n} {B}_{i} \qquad ( 4 )$$

where,

R is the ratio to be calculated, which is an estimation for the relative excess demand;

Fᵢ is the number of flows arriving at server 101 (FIG. 2) in service class i,

Gᵢ is the number of flows admitted for transmission to end user devices 110 in service class i,

Hᵢ is the number of flows dropped after being admitted in service class i,

Bᵢ is the number of bytes (representing volume of data) that were transmitted to end user devices 110 in service class i,

and Kᵢ is a weighting factor that represents the excess amount of resources required for service class i due to the burst-oriented nature of the data service or application associated with service class i.

The weighting factors Kᵢ above can be tuned empirically by setting different values for every factor Kᵢ, measuring the accuracy of the resulting estimation for the relative excess demand in a live cellular network, and retuning the values to improve the estimation accuracy. Initial values for the weighting factors Kᵢ, can be, for example, 2.0 for service classes associated with interactive service type, 1.5 for download service type, and 1.0 for streaming service type.

The process ends at block 409. This process can be repeated for as many cycles as desired.

The methods and apparatus disclosed herein have been described with exemplary reference to specific hardware and/or software. The methods have been described as exemplary, whereby specific steps and their order can be omitted and/or changed by persons of ordinary skill in the art to reduce embodiments of the present invention to practice without undue experimentation. The methods and apparatus have been described in a manner sufficient to enable persons of ordinary skill in the art to readily adapt other commercially available hardware and software as may be needed to reduce any of the embodiments of the present invention to practice without undue experimentation and using conventional techniques.

While preferred embodiments of the present invention have been described, so as to enable one of skill in the art to practice the present invention, the preceding description is intended to be exemplary only. It should not be used to limit the scope of the invention, which should be determined by reference to the following claims.

What is claimed is:

1. A method for monitoring and controlling data traffic in cellular networks, comprising:
establishing at least one service class;
continuously monitoring Quality of Service (QoS) parameters for said at least one service class; and
continuously controlling said QoS parameters for said at least one service class based on service level parameters.

2. The method of claim 1, wherein said monitoring said QoS parameters includes, continuously obtaining the capacity of said at least one cell.

3. The method of claim 2, wherein said continuously obtaining the capacity of said at least one cell includes, monitoring flow control signaling associated with said at least one cell.

4. The method of claim 2, wherein said continuously obtaining the capacity of said at least one cell includes:
estimating available resources based on said monitored flow control signaling associated with said at least one cell.

5. The method of claim 2, wherein said continuously obtaining the capacity of said at least one cell includes:
monitoring accumulated delay associated with said at least one service class.

6. The method of claim 5, wherein said continuously obtaining the capacity of said at least one cell includes:
estimating available resources based on said monitored accumulated delay associated with said at least one cell.

7. The method of claim 2, wherein said continuously obtaining the capacity of said at least one cell includes:
monitoring flow control signaling associated with said at least one cell; and
monitoring accumulated delay associated with said at least one service class.

8. The method of claim 7, wherein said continuously obtaining the capacity of said at least one cell includes:
estimating available resources based on said monitored flow control signaling associated with said at least one cell; and on said monitored accumulated delay associated with said at least one cell.

9. The method of claim 1, wherein said establishing one service class includes, defining flow parameters.

10. The method of claim 1, additionally comprising:
establishing service plans.

11. The method of claim 1, wherein said QoS parameters for said at least one service class include at least one of blocking rate, dropping rate, rejection rate or termination rate.

12. The method of claim 1, wherein said service level parameters include absolute priorities and relative priorities.

13. The method of claim 1, wherein said service level parameters include target blocking and target dropping.

14. The method of claim 1, wherein said continuously controlling said QoS parameters for said at least one service class includes modifying resource allocation for said at least one service class.

15. The method of claim 14, wherein said modifying resource allocation includes modifying said service level parameters.

16. A server for monitoring and controlling data traffic in cellular networks, comprising:
a processor programmed to:
establish at least one service class;
continuously monitor Quality of Service (QoS) parameters for said at least one service class; and
continuously control said QoS parameters for said at least one service class based on service level parameters.

17. The server of claim 16, wherein said processor programmed to monitor said QoS parameters is additionally programmed to continuously obtaining the capacity of said at least one cell.

18. The server of claim 17, wherein said processor programmed to continuously obtaining the capacity of said at least one cell is additionally programmed to monitor flow control signaling associated with said at least one cell.

19. The server of claim 17, wherein said processor programmed to continuously obtaining the capacity of said at least one cell is additionally programmed to, estimate available resources based on said monitored flow control signaling associated with said at least one cell.

20. The server of claim 17, wherein said processor programmed to continuously obtaining the capacity of said at least one cell is additionally programmed to, monitor accumulated delay associated with said at least one service class.

21. The server of claim 20, wherein said processor programmed to obtain the capacity of said at least one cell is additionally programmed to:
estimate available resources based on said monitored accumulated delay associated with said at least one cell.

22. The server of claim 17, wherein said processor programmed to continuously obtaining the capacity of said at least one cell is additionally programmed to:
monitor flow control signaling associated with said at least one cell; and
monitor accumulated delay associated with said at least one service class.

23. The server of claim 22, wherein said processor programmed to obtain the capacity of said at least one cell is additionally programmed to:
estimate available resources based on said monitored flow control signaling associated with said at least one cell; and on said monitored accumulated delay associated with said at least one cell.

24. The server of claim 16, wherein said processor is additionally programmed to:
establish service plans.

25. The server of claim 16, wherein said processor programmed to continuously control said QoS parameters for said at least one service class, is additionally programmed to: modify resource allocations for said at least one service class.

26. The server of claim 25, wherein said processor programmed to modify resource allocation, is additionally programmed to modify said service level parameters.

27. A programmable storage device readable by a machine, tangibly embodying a program of instructions executable by a machine to perform method steps for controlling traffic in a data network, said method steps selectively executed during the time when said program of instructions is executed on said machine, comprising:
establishing at least one service class;
continuously monitoring Quality of Service (QoS) parameters for said at least one service class; and
continuously controlling said QoS parameters for said at least one service class based on service level parameters.

28. A method for network dimensioning, comprising:
establishing at least one service class;
continuously monitoring Quality of Service (QoS) parameters for said at least one service class; and
estimating resources required to accommodate excess demand.

29. The method of claim 28, wherein said continuously monitoring said QoS parameters includes, continuously obtaining the capacity of said at least one cell.

30. The method of claim 29, wherein said continuously obtaining the capacity of said at least one cell includes, monitoring flow control signaling associated with said at least one cell.

31. The method of claim 29, wherein said continuously obtaining the capacity of said at least one cell includes:
estimating available resources based on said monitored flow control signaling associated with said at least one cell.

32 The method of claim 29, wherein said continuously obtaining the capacity of said at least one cell includes:
monitoring accumulated delay associated with said at least one service class.

33. The method of claim 32, wherein said continuously obtaining the capacity of said at least one cell includes:
estimating available resources based on said monitored accumulated delay associated with said at least one cell.

34. The method of claim 29, wherein said continuously obtaining the capacity of said at least one cell includes:
monitoring flow control signaling associated with said at least one cell; and
monitoring accumulated delay associated with said at least one service class.

35. The method of claim 34, wherein said continuously obtaining the capacity of said at least one cell includes:
estimating available resources based on said monitored flow control signaling associated with said at least one cell; and on said monitored accumulated delay associated with said at least one cell.

36. The method of claim 28, wherein said establishing one service class includes, defining flow parameters.

37. The method of claim 28, additionally comprising:
establishing service plans.

38. The method of claim 28, wherein said QoS parameters for said at least one service class include at least one of blocking rate, dropping rate, rejection rate or termination rate.

39. The method of claim 28, wherein said estimating resources required to accommodate excess demand includes calculating normalized demand and normalized cell resources.

40. The method of claim 28, wherein said accommodating excess demand includes accommodating all new flows, while satisfying per flow parameters.

41. The method of claim 28, wherein said accommodating excess demand includes accommodating new flows to satisfy service level parameters and per flow parameters.

42. The method of claim 41, wherein said service level parameters include target blocking and target dropping.

43. The method of claim 28, wherein said accommodating excess demand includes maintaining all flows, whereby none of said flows are dropped, while satisfying per flow parameters.

44. The method of claim 28, wherein said accommodating excess demand includes dropping flows while satisfying service level parameters and per flow parameters.

45. The method of claim 44, wherein said service level parameters include target blocking and target dropping.

46. A server for network dimensioning, comprising:
a processor programmed to:
establish at least one service class;
continuously monitor Quality of Service (QoS) parameters for said at least one service class; and
estimate resources required to accommodate excess demand.

47. The server of claim 46, wherein said processor programmed to continuously monitor said QoS parameters is additionally programmed to, continuously obtain the capacity of said at least one cell.

48. The server of claim 47, wherein said continuously obtaining the capacity of said at least one cell includes, monitoring flow control signaling associated with said at least one cell.

50. The server of claim 47, wherein said continuously obtaining the capacity of said at least one cell includes:
estimating available resources based on said monitored flow control signaling associated with said at least one cell.

51. The server of claim 47, wherein said continuously obtaining the capacity of said at least one cell includes:
monitoring accumulated delay associated with said at least one service class.

52. The server of claim 47, wherein said continuously obtaining the capacity of said at least one cell includes:
estimating available resources based on said monitored accumulated delay associated with said at least one cell.

53. The server of claim 47, wherein said continuously obtaining the capacity of said at least one cell includes:
monitoring flow control signaling associated with said at least one cell; and
monitoring accumulated delay associated with said at least one service class.

54. The server of claim 53, wherein said continuously obtaining the capacity of said at least one cell includes:
estimating available resources based on said monitored flow control signaling associated with said at least one cell; and on said monitored accumulated delay associated with said at least one cell.

55. The server of claim 46, wherein said processor programmed to establish one service class, is additionally programmed to define flow parameters.

56. The server of claim 46, wherein said processor is additionally programmed to:
establish service plans.

57. The server of claim 46, wherein said processor programmed to estimate resources required to accommodate excess demand is additionally programmed to calculate normalized demand and normalized cell resources.

58. A programmable storage device readable by a machine, tangibly embodying a program of instructions executable by a machine to perform method steps for controlling traffic in a data network, said method steps selectively executed during the time when said program of instructions is executed on said machine, comprising:
establishing at least one service class;
continuously monitoring Quality of Service (QoS) parameters for said at least one service class; and
estimating resources required to accommodate excess demand.
